(19) United States
(12) Patent Application Publication
(10) Pub. No.: US 2025/0107205 A1
(43) Pub. Date: Mar. 27, 2025

(54) SEMICONDUCTOR DEVICE WITH OFFSET GATE CONTACT

(71) Applicant: INTERNATIONAL BUSINESS MACHINES CORPORATION, ARMONK, NY (US)

(72) Inventors: Albert M. Chu, Nashua, NH (US); Brent A. Anderson, Jericho, VT (US); Ravikumar Ramachandran, Pleasantville, NY (US)

(21) Appl. No.: 18/371,015

(22) Filed: Sep. 21, 2023

(51) Int. Cl. H01L 29/417

(52) U.S. Cl. CPC H10D 64/258; H10D 64/254

(57) ABSTRACT

A semiconductor device is provided. The semiconductor device includes an active region, a gate, a gate contact formed on the gate, the gate contact overlapping in plan view with at least a portion of the active region, and a source/drain contact formed on the active region and adjacent to the gate contact. The gate contact is offset from a centerline of the gate in a direction away from the source/drain contact.

### BACKGROUND

The present disclosure relates to fabrication methods and resulting structures for semiconductor devices. More specifically, the present disclosure relates to fabrication methods and resulting structures for semiconductor devices including a gate contact formed over an active region of the semiconductor device.

In certain semiconductor device fabrication processes, a large number of semiconductor devices, such as n-type field effect transistors (nFETs) and p-type field effect transistors (pFETs), may be fabricated on a single wafer. Non-planar transistor device architectures (e.g., fin-type FETs (FinFETs) and nanosheet FETs) can provide increased device density and increased performance over planar transistors. Because of the continuing trend toward decreasing the overall size and/or critical dimensions of the various individual structures in such semiconductor devices, it may be desirable to increase the flexibility with regard to where certain metal contacts (e.g., a gate contact) are placed.

In certain semiconductor structures, the gate contact may be in a location so as to not overlap with the active region when viewed in plan view, and in these examples the gate contact may be located over the gate region but between adjacent active regions (i.e., as opposed to overlapping the active region).

### SUMMARY

Embodiments of the present disclosure relate to a semiconductor device. The semiconductor device includes an active region, a gate, a gate contact formed on the gate, the gate contact overlapping in plan view with at least a portion of the active region, and a source/drain contact formed on the active region and adjacent to the gate contact. The gate contact is offset from a centerline of the gate in a direction away from the source/drain contact.

Embodiments of the present disclosure relate to a semiconductor device. The semiconductor device includes an active region, a first gate and a second gate, a first gate contact formed on the first gate, and a second gate contact formed on the second gate, the first and second gate contacts overlapping in plan view with at least a portion of the active region, and a first source/drain contact on the active region and adjacent to the first gate contact, and a second source/drain contact on the active region and adjacent to the second gate contact. The first gate contact is offset from a centerline of the gate in a first offset direction away from the first source/drain contact. The second gate contact is offset from a centerline of the gate in a second offset direction away from the second source/drain contact, and the first offset direction is different from the second offset direction.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1A is a partial cross-sectional view of a semiconductor device including a gate contact that is not offset from a centerline of the gate, and taken along the A line of FIG. 1B, according to embodiments.

FIG. 1B is a simplified top view of the semiconductor device shown in FIG. 1A, according to embodiments.

FIG. 2A is a partial cross-sectional view of a semiconductor device including a gate contact that is offset from a centerline of the gate, and taken along the B line of FIG. 2B, according to embodiments.

FIG. 2B is a simplified top view of the semiconductor device shown in FIGS. 2A and 2C, according to embodiments.

FIG. 2C is a partial cross-sectional view of the semiconductor device of FIG. 2A including a gate contact that is offset from a centerline of the gate, and taken along the C line of FIG. 2B, according to embodiments.

FIG. 3 is a partial cross-sectional view of a semiconductor device including a gate contact that is offset from a centerline of the gate and extends beyond an edge of the gate, according to embodiments.

FIG. 4 is a partial cross-sectional view of a semiconductor device including a gate contact that extends across a source/drain epitaxial layer and connects to two gates, according to embodiments.

FIG. 5 is a partial cross-sectional view a semiconductor device including a gate contact that is offset from a centerline of the gate and extends to accommodate contact with a source/drain contact via, according to embodiments.

FIG. 6 is a simplified top view of a semiconductor device showing certain gate contacts that are offset from a centerline of the gate, and other gate contacts that are not offset, according to embodiments.

FIG. 7 is a flowchart of an example method for setting a position of a gate contact relative to a centerline of a gate for a semiconductor device, according to embodiments.

FIG. 8 is a simplified top view of a semiconductor device showing a gate contact that has source/drain contacts on both sides of the gate contact, according to embodiments.

### DETAILED DESCRIPTION

The present disclosure describes semiconductor devices including an offset gate contact formed over an active region of the semiconductor device, and methods of manufacturing the semiconductor devices. In particular, the present disclosure describes certain embodiments including at least one gate contact that is formed at least partially over the active region of the device, where the gate contact is offset from a centerline of the gate region (also referred to as a channel region) and away from a source/drain contact (also referred to as an epitaxial contact).

However, when moving the location of the gate contact (CB) to overlap with the active region (RX) in plan view (or top down view), the gate contact might be very close to one or more of the source/drain contacts (CA), and this has the potential to cause electrical shorting between the gate contact and the source/drain contacts. Also, with the trend toward structures with smaller critical dimensions, patterning the gate contact to overlap in plan view with the active region becomes more difficult because of the potential for misalignment and electrical shorting. In semiconductor devices that include an active region, a gate contact, and a source/drain contact, as the transistor gate pitch (also referred to as the contacted poly pitch or CPP) shrinks, the gate contact space to source/drain contact is reduced, causing a reduction in Vₘₐₓ (or maximum operating voltage of the semiconductor device).

Having the gate contact over the active region may be beneficial for the middle of line (MOL) design to enable flexible placement of various other metal contacts, such as the source/drain contacts. In the present embodiments, due to the fact that the gate contact is offset with respect to a centerline of the gate region, this may decrease the potential for electrical shorting with the source/drain contact. The offset gate may also enable an increase in the Vₘₐₓ of the semiconductor device. In addition, the offset gate contact may also allow for increased flexibility with regard to being able to form other contacts in different areas (i.e., because these areas are not occupied by the gate contact).

The flowcharts and cross-sectional diagrams in the Figures illustrate methods of manufacturing semiconductor devices according to various embodiments. In some alternative implementations, the manufacturing steps may occur in a different order that that which is noted in the Figures, and certain additional manufacturing steps may be implemented between the steps noted in the Figures. Moreover, any of the layered structures depicted in the Figures may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the particular drawing figures. Several of the figures show different orientation such as the top view, and different cross-sectional views. It should be noted that right and left, or top and bottom, etc. relate to (or depend on) the particular view of each figure. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes may be followed by furnace annealing or by rapid thermal annealing (RTA), which serve to activate the implanted dopants. Films of both conductors (e.g., poly-silicon, aluminum, copper, etc.) and insulators (e.g., various forms of silicon dioxide, silicon nitride, etc.) may be used to connect and isolate transistors and their components. Selective doping of various regions of the semiconductor substrate may allow the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns may be formed by a light sensitive polymer called a photo-resist. To build the complex structures that make up a transistor and the many wires that connect the millions of transistors of a circuit, lithography and etch pattern transfer operations may be repeated multiple times. Each pattern being printed on the wafer is aligned to the previously formed patterns and slowly the conductors, insulators and selectively doped regions may be built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions.

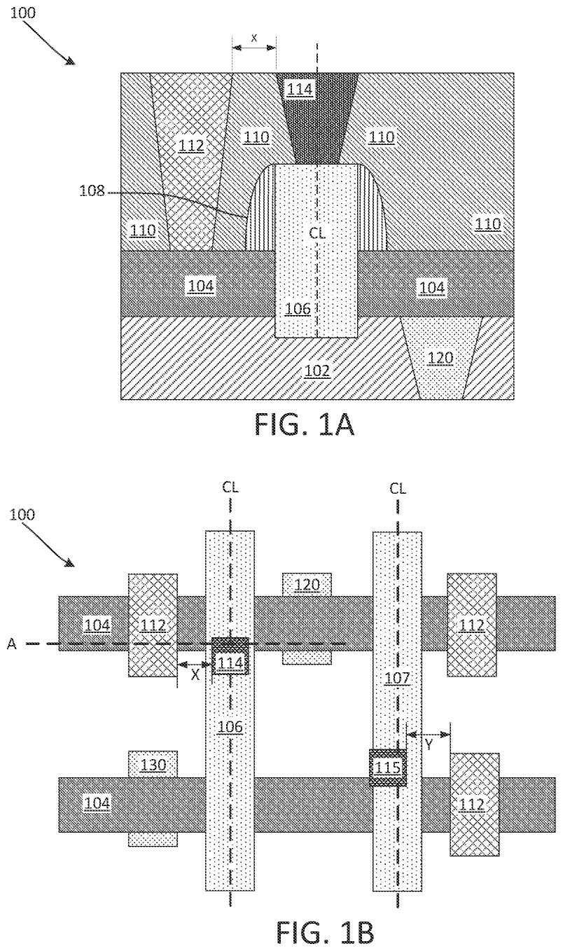

Referring now to the drawings in which like numerals represent the same or similar elements and initially to FIG. 1A, this figure is a partial cross-sectional view of a semiconductor device taken along the A line of FIG. 1B, according to embodiments. It should be appreciated that FIGS. 1A and 1B show an example of a semiconductor device including a first gate contact 114 that is centered (or not offset) with a first gate 106, and a second gate contact 115 that is centered with a second gate 107. As shown in FIG. 1A, a substrate 102 is provided. The substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor on insulator (SOI) substrate. Other illustrative examples of semiconductor materials that can be used in the present application include, but are not limited to, silicon (Si), a silicon germanium (SiGe) alloy, a silicon germanium carbide (SiGeC) alloy, germanium (Ge), a III/V compound semiconductor, an II/VI compound semiconductor or a multilayered stack including at least two semiconductor materials (e.g., a multilayered stack of Si and SiGe). In one embodiment (depicted in the drawings of the present application), the semiconductor substrate 102 is entirely composed of at least one semiconductor material. It should be appreciated that the substrate 102 may also be comprised of one or more other suitable material(s) than those listed above.

Referring again to FIG. 1A, in certain examples, one or more backside contacts 120 may be formed in the substrate 102 layer. The backside contacts 120 may be formed by first forming a recess (not shown) in the substrate 102 by any suitable material removal process (e.g., etching), and then depositing the material of the backside contacts 120 into the recess. In certain embodiments, after the formation of the backside contacts 120, a suitable material removal process such as CMP may be performed on the semiconductor device 100 to planarize the surfaces of the substrate 102 and the backside contacts 120.

The semiconductor device 100 includes a channel region that includes a first gate 106 (also referred to as a gate region, or gate electrode). The gate 106 comprises one or more suitable electrically conductive metals (e.g., Cu). In certain examples, the gate 106 may be partially formed into the substrate 102. In these examples, prior to forming the first gate 106, an amount of the material of the substrate 102 may be removed with a suitable material removal technique such as etching. It should be appreciated that in other examples a bottom surface of the first gate 106 may be flush with a top surface of the substrate 102.

As also shown in FIG. 1A, the active region including source/drain epitaxial layers 104 is formed on each side of the first gate 106. In certain examples, the first gate 106 extends above an upper surface of the source/drain epitaxial layers 104. In certain embodiments, a gate electrode spacer layer 108 is formed on both sides of the first gate 106. The gate electrode spacer layer 108 may comprise one or more suitable dielectric materials. Also, an interlayer dielectric (ILD) layer 110 is formed on the source/drain epitaxial layers 104 and on the gate electrode spacer layer 108. The ILD layer 110 may comprise one or more suitable dielectric materials. As shown in FIG. 1A, the gate electrode spacer layer 108 is formed on the sides of the first gate 106, and is formed between the first gate 106 and the ILD layer 110. After the formation of the ILD layer 110, a suitable material removal process may be used to form trenches (not shown) in the ILD layer 110 that expose the upper surface of at least one of the source/drain epitaxial layers 104. In the example shown in FIG. 1A, a trench is formed through the ILD layer 110 on the left side of the first gate 106 to expose the source/drain epitaxial layer 104 on that side. Then, one or more suitable metallic materials are deposited into the trench and on the source/drain epitaxial layer 104 to form a source/drain contact 112 (also referred to as CA contacts). Also, a similar material removal process is performed on the ILD layer 110 to form another trench (not shown), thereby exposing the first gate 106. Then, one or more suitable metallic materials are deposited into this trench and on the first gate 106 (also referred to as a CB contact) to form the gate contact 114.

Referring now to FIG. 1B, this figure is a simplified top view of the semiconductor device 100 shown in FIG. 1A, according to embodiments. As shown in FIG. 1B, the source/drain epitaxial layers 104, which are included in the active region of the semiconductor device 100, extend in a first direction. The channel regions including the first gate 106 and the second gate 107 extend in a second direction that is orthogonal to the first direction in plan view (or top-down view). Thus, the first gate 106 overlaps in plan view with the active area of the source/drain epitaxial layers 104 (e.g., FIGS. 1B, 2B and 6 show a plan view or top view perspective). A number of backside contacts 120 and 130 are formed under the source/drain epitaxial layers 104. The backside contact 120 may be a drain contact (or VDD contact), and the backside contact 130 may be a source contact (or VSS contact). A number of the source/drain contacts 112 (also referred to as CA) are formed over the source/drain epitaxial layers 104, a first gate contact 114 (also referred to as CB) is formed over the first gate 106, and a second gate contact 115 is formed over the second gate contact 115. In the example shown in FIG. 1B, in addition to the first gate contact 114 overlapping the first gate 106 in plan view, the first gate contact 114 also at least partially overlaps in plan view with the source/drain epitaxial layers 104 that are included in the active region of the semiconductor device 100. Also, a second gate 107 is shown that also overlaps in plan view with the active area of the source/drain epitaxial layers 104.

As also shown in FIG. 1B, in this example, the first gate contact 114 is aligned with a centerline (CL) of the first gate 106. Thus, as discussed herein, as the CPP (or contacted poly pitch, which is a measure of how close or how far apart each gate is) between device components continues to get smaller, the distance X between the first gate contact 114 to the adjacent source/drain contact 112 is reduced, and this may cause a reduction in Vₘₐₓ. Regarding the effect of the distance between the gate contact and the source/drain contact on the Vₘₐₓ, similar to a capacitor, the larger the distance between the adjacent components, the larger a voltage that the semiconductor device is able to sustain for breakdown. Thus, there may be a desire to improve the Vₘₐₓ by increasing the distance X between the gate contact 114 and the source/drain contact 112. As shown in FIG. 1B, in certain examples, there may be a plurality of different gate contacts, where the first gate contact 114 is positioned to the right of the adjacent source/drain contact 112, and where a second gate contact 115 is positioned to the left of the adjacent source/drain contact 112. As shown in FIG. 1B, the second gate contact 115 is offset from a centerline of the second gate 107, which increases the distance from X to Y. The embodiments herein further discuss examples where at least one of the gate contacts that overlaps the active region, and is adjacent to a source/drain contact, is offset in a direction away from the respective adjacent source/drain contact 112.

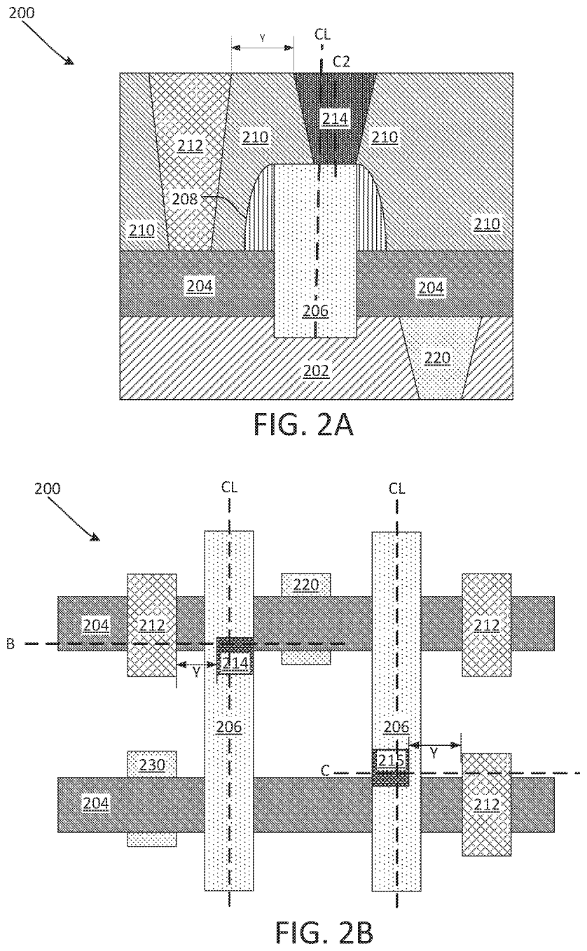

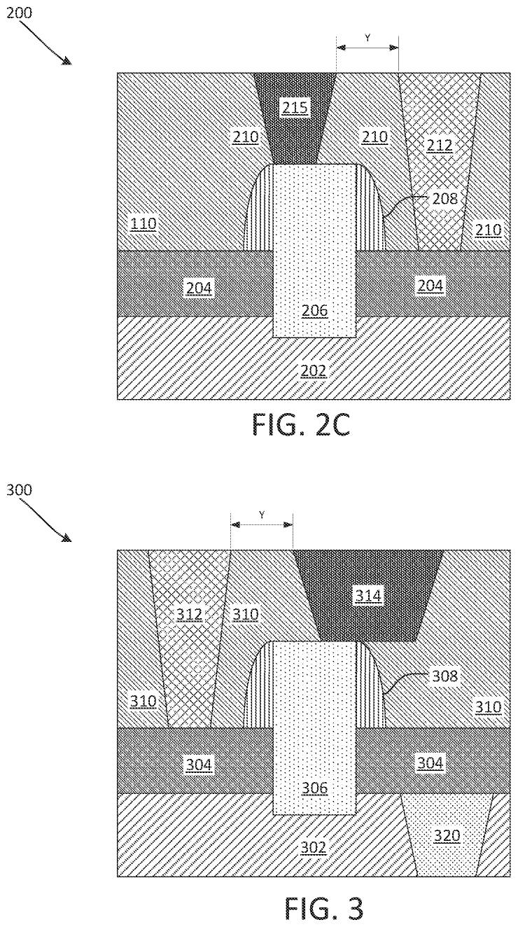

FIG. 2A is a partial cross-sectional view of a semiconductor device taken along the B line of FIG. 2B, according to embodiments. It should be appreciated that FIGS. 2A-2C show an example of a semiconductor device 200 including a gate contact 214 that is offset relative to a centerline (CL) of the gate 206. In other words, a center (C2) of the gate contact 214 is offset from the centerline CL of the gate 206. It should be appreciated that this concept of “offset” of the gate to gate contact may be applied to the other embodiments described herein. As shown in FIG. 2A, a substrate 202 is provided. The substrate 202 may be comprised of the same or different materials as described above with respect to FIGS. 1A and 1B. In certain examples, one or more backside contacts 220 may be formed in the substrate 202 layer. The backside contacts 220 may be formed by first forming a recess (not shown) in the substrate 202 by any suitable material removal process (e.g., etching), and then depositing the material of the backside contacts 220 into the recess. In certain embodiments, after the formation of the backside contacts 220, a suitable material removal process such as CMP may be performed on the semiconductor device 200 to planarize the surfaces of the substrate 202 and the backside contacts 220.

The semiconductor device 200 includes a gate 206 (also referred to as a gate region, or gate electrode). The gate 206 comprises one or more suitable electrically conductive metals (e.g., Cu). In certain examples, the gate 206 may be partially formed into the substrate 202. In these examples, prior to forming the gate 206, an amount of the material of the substrate 202 may be removed with a suitable material removal technique such as etching. It should be appreciated that in other examples a bottom surface of the gate 206 may be flush with a top surface of the substrate 202.

As also shown in FIG. 2A, source/drain epitaxial layers 204 are formed on each side of the gate 206. In certain examples, the gate 206 extends above an upper surface of the source/drain epitaxial layers 204. In certain embodiments, a gate electrode spacer layer 208 is formed on both sides of the gate 206. The gate electrode spacer layer 208 may comprise one or more suitable dielectric materials. Also, an interlayer dielectric (ILD) layer 210 may be formed on the source/drain epitaxial layers 204 and the gate electrode spacer layer 208. The ILD layer 210 may comprise one or more suitable dielectric materials. As shown in FIG. 2A, the gate electrode spacer layer 208 is formed on the sides of the gate 206, and is formed between the gate 206 and the ILD layer 210. After the formation of the ILD layer 210, a suitable material removal process may be used to form trenches (not shown) in the ILD layer 210 that expose the upper surface of at least one of the source/drain epitaxial layers 204. In the example shown in FIG. 2A, a trench is formed through the ILD layer 210 on the left side of the gate 206 to expose the source/drain epitaxial layer 204 on that side. Then, one or more suitable metallic materials are deposited into the trench and on the source/drain epitaxial layer 204 to form a source/drain contact 212 (also referred to as CA contacts). Also, a similar material removal process may be performed on the ILD layer 210 to form another trench (not shown), thereby exposing the gate 206. Then, one or more suitable metallic materials may be deposited into this trench and on the gate contact 214 (also referred to as a CB contact) is formed on the gate 206.

As shown in FIG. 2A, there is a portion of the gate contact 214 that directly contacts the upper surface of the gate 206, but does not directly contact the entire upper surface of the gate 206. Therefore, in certain examples, the gate contact 214 only partially covers the gate 206, and there is a remaining portion of the gate 206 that is not covered by the gate contact 214 (i.e., the ILD layer 210 is covering the remaining portion of the gate 206 that is not covered by the gate contact 214). It should be appreciated that this concept of the gate contact covering a portion of the gate applies to the embodiments shown in FIGS. 3-5 as well.

FIG. 2B is a simplified top view of the semiconductor device 200 shown in FIGS. 2A and 2C, according to embodiments. As shown in FIG. 2B, the source/drain epitaxial layers 204 (also referred to as the active area (or RX) of the semiconductor device 200) extend in a first direction. The gates 206 extend in a second direction that is orthogonal to the first direction. Thus, the gates 206 intersect with the active area of the source/drain epitaxial layers 204. A number of the backside contacts 220 and 230 are formed under the source/drain epitaxial layers 204. The backside contact 220 may be a drain contact (or VDD contact), and the backside contact 230 may be a source contact (or VSS contact). A number of the source/drain contacts 212 (also referred to as CA) are formed over the source/drain epitaxial layers 204, and a number of gate contacts 214 and 215 (also referred to as CB) are formed over the gates 206. In the example shown in FIG. 2B, in addition to the gate contacts 214 overlapping the gate 206 in plan view, the gate contacts 214 also at least partially overlap in plan view with the source/drain epitaxial layers 204.

As also shown in FIG. 2B, in this example, the gate contacts 214 and 215 are not aligned with a centerline (CL) of the gate 206. Thus, a distance Y between the gate contacts 214 and 215 to the source/drain contact 212 is increased relative to the corresponding distance X discussed above with respect to FIGS. 1A and 1B (i.e., Y>X), and this may enable an increase in the Vₘₐₓ. As shown in FIG. 2B, in certain examples, there may be a plurality of different gate contacts 214 and 215, where one or more of the gate contacts 214 are positioned to the right of the adjacent source/drain contact 212, and where one or more of the gate contacts 215 are positioned to the left of the adjacent source/drain contact 212.

In the case of the gate contact 214 shown in the cross-sectional view of FIG. 2A, the gate contact 214 is shifted to the right of (or offset from) the CL of the gate 206 so as to be further away from the adjacent source/drain contact 212. Also, as shown in FIG. 2C (which is a partial cross-sectional view of the semiconductor device of FIG. 2A taken along the C line of FIG. 2B), the gate contact 215 is shifted to the left of the CL of the gate 206 so as to be further away from the adjacent source/drain contact 212. Therefore, in examples where there is more than one offset gate contacts 214 and 215, the direction of the offset can be in different directions depending on where the source/drain contact 212 is located. That is, in certain embodiments, the gate contacts 214 and 215 are shifted so as to be located further away from the source/drain contact 212, while still maintaining an electrical connection between the respective gate 206 and gate contacts 214 and 215. It should be appreciated that the shifting of the location of the gate contacts 214 and 215 may occur regardless of the proximity of the backside contact 220. That is, in FIG. 2A, the gate contact 214 location is shifted when the backside contact 220 is present, and in FIG. 2C, the gate contact 215 location is also shifted even though the backside contact 220 is not present.

FIG. 3 is a partial cross-sectional view of a semiconductor device 300 including a gate contact 314 that is offset from a centerline of the gate 306 and extends beyond an edge of the gate 306, according to embodiments. As shown in FIG. 3, a substrate 302 is provided. The substrate 302 may be comprised of the same or different materials as described above with respect to the other embodiments. In certain examples, one or more backside contacts 320 may be formed in the substrate 302 layer. The backside contacts 320 may be formed by first forming a recess (not shown) in the substrate 302 by any suitable material removal process (e.g., etching), and then depositing the material of the backside contacts 320 into the recess. In certain embodiments, after the formation of the backside contacts 320, a suitable material removal process such as CMP may be performed on the semiconductor device 300 to planarize the surfaces of the substrate 302 and the backside contacts 320.

The semiconductor device 300 includes a gate 306 (also referred to as a gate region, or gate electrode). The gate 306 comprises one or more suitable electrically conductive metals (e.g., Cu). In certain examples, the gate 306 may be partially formed into the substrate 302. In these examples, prior to forming the gate 306, an amount of the material of the substrate 302 may be removed with a suitable material removal technique, such as etching. It should be appreciated that in other examples a bottom surface of the gate 306 may be flush with a top surface of the substrate 302.

As also shown in FIG. 3, source/drain epitaxial layers 304 are formed on each side of the gate 306. In certain examples, the gate 306 extends above an upper surface of the source/drain epitaxial layers 304. In certain embodiments, a gate electrode spacer layer 308 is formed on both sides of the gate 306. The gate electrode spacer layer 308 may comprise one or more suitable dielectric materials. Also, an interlayer dielectric (ILD) layer 310 is formed on the source/drain epitaxial layers 304 and the gate electrode spacer layer 308. The ILD layer 310 may comprise one or more suitable dielectric materials. As shown in FIG. 3, the gate electrode spacer layer 308 is formed on the sides of the gate 306, and is formed between the gate 306 and the ILD layer 310. After the formation of the ILD layer 310, a suitable material removal process may be used to form trenches (not shown) in the ILD layer 310 that expose the upper surface of at least one of the source/drain epitaxial layers 304. In the example shown in FIG. 3, a trench is formed through the ILD layer 310 on the left side of the gate 306 to expose the source/drain epitaxial layer 304 on that side. Then, one or more suitable metallic materials are deposited into the trench and on the source/drain epitaxial layer 304 to form a source/drain contact 312 (also referred to as CA contacts). Also, a similar material removal process is performed on the ILD layer 310 to form another trench (not shown), thereby exposing the gate 306 and a portion of the ILD layer 310. Then, one or more suitable metallic materials are deposited into this trench and the gate contact 314 (also referred to as a CB contact) is formed on the gate 306 and the ILD layer 310.

In the embodiment shown in FIG. 3, the offset between the source/drain contact 312 and the gate contact 314 is increased, similar to the offsets that were discussed above with respect to FIGS. 2A-2C. However, in the embodiments of FIG. 3, the gate contact 312 is made to be wider so as to have an extension (or extension portion that extends beyond the right side edge of the gate 306) that is located over the source/drain epitaxial layer 304 to the right of the gate 306. The reason for the wider gate contact 312 is to improve the contact area for a via (not shown) to subsequently be formed on the gate contact 312. Thus, a distance Y between the gate contact 314 to the source/drain contact 312 is larger that it would be if the gate contact 314 was aligned with the centerline (CL) of the gate, and this larger distance may enable an increase in the Vₘₐₓ.

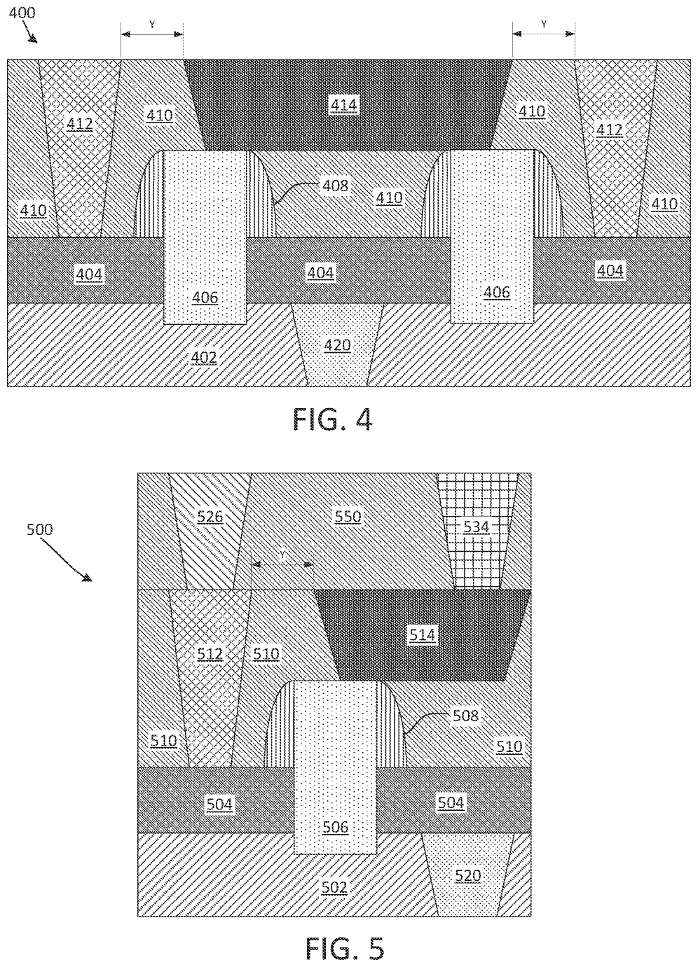

FIG. 4 is a partial cross-sectional view of a semiconductor device 400 including a gate contact 414 that is offset from a centerline of the gate 406 and extends across a source/drain epitaxial layer 404 to contact two different gates 406 (i.e., a merged gate contact), according to embodiments. As shown in FIG. 4, a substrate 402 is provided. The substrate 402 may be comprised of the same or different materials as described above with respect to the other embodiments. In certain examples, one or more backside contacts 420 may be formed in the substrate 402 layer. The backside contacts 420 may be formed by first forming a recess (not shown) in the substrate 402 by any suitable material removal process (e.g., etching), and then depositing the material of the backside contacts 420 into the recess. In certain embodiments, after the formation of the backside contacts 420, a suitable material removal process such as CMP may be performed on the semiconductor device 400 to planarize the surfaces of the substrate 402 and the backside contacts 420.

The semiconductor device 400 includes a plurality of gates 406 (also referred to as a gate regions, or gate electrodes). The gates 406 comprises one or more suitable electrically conductive metals (e.g., Cu). In certain examples, the gates 406 may be partially formed into the substrate 402. In these examples, prior to forming the gates 406, an amount of the material of the substrate 402 may be removed with a suitable material removal technique, such as etching. It should be appreciated that in other examples a bottom surface of the gates 406 may be flush with a top surface of the substrate 402.

As also shown in FIG. 4, source/drain epitaxial layers 404 are formed on each side of the two gates 406, for a total of three different source/drain epitaxial layers 404. In certain examples, the gates 406 extend above an upper surface of the source/drain epitaxial layers 404. In certain embodiments, a gate electrode spacer layer 408 is formed on both sides of the gates 406. The gate electrode spacer layer 408 may comprise one or more suitable dielectric materials. Also, an interlayer dielectric (ILD) layer 410 is formed on the source/drain epitaxial layers 404 and the gate electrode spacer layer 408. The ILD layer 410 may comprise one or more suitable dielectric materials.

As shown in FIG. 4, the gate electrode spacer layer 408 is formed on the sides of the gates 406, and is formed between the gates 406 and the ILD layer 410. After the formation of the ILD layer 410, a suitable material removal process may be used to form trenches (not shown) in the ILD layer 410 that expose the upper surface of right and left source/drain epitaxial layers 404. In the example shown in FIG. 4, the trenches are formed through the ILD layer 410 on the left side of the leftmost gate 406 and the right side of the rightmost gate 406 to expose the respective source/drain epitaxial layers 404 on those sides. Then, one or more suitable metallic materials are deposited into these trenches and on the source/drain epitaxial layers 404 to form the source/drain contact 412 (also referred to as CA contacts). Also, a similar material removal process is performed on the ILD layer 410 to form another trench (not shown), thereby exposing both of the two gates 406 and a portion of the ILD layer 410 that bridges to two gates 406. Then, one or more suitable metallic materials are deposited into this trench and the bridged gate contact 414 (also referred to as a CB contact) is formed on both of the gates 406 and the ILD layer 410.

In the embodiment shown in FIG. 4, the offset between the source/drain contact 412 and the gate contact 414 is increased, similar to the offsets that were discussed above with respect to FIGS. 2A-2C and 3. However, in the embodiments of FIG. 4, the gate contact 412 is made to be even wider so as to have a merged gate contact structure that contacts both of the gates 406. In certain examples, there may be a need to connect the gates together. By using a wider gate contact 412 to make this connection, the use of vias and metal wires to this make this connection may not be needed. Thus, a distance Y between the gate contact 414 to the two different source/drain contacts 412 is increased relative to the distance X discussed above with respect to FIGS. 1A and 1B (i.e., Y>X), and this may enable an increase in the Vₘₐₓ.

FIG. 5 is a partial cross-sectional view a semiconductor 500 device including a gate contact 514 that is offset from a centerline of the gate 506 and that is wide enough to allow for the landing of a gate contact via 534, according to embodiments. As shown in FIG. 5, a substrate 502 is provided. The substrate 502 may be comprised of the same or different materials as described above with respect to the other embodiments. In certain examples, one or more backside contacts 520 may be formed in the substrate 502 layer. The backside contacts 520 may be formed by first forming a recess (not shown) in the substrate 502 by any suitable material removal process (e.g., etching), and then depositing the material of the backside contacts 520 into the recess. In certain embodiments, after the formation of the backside contacts 520, a suitable material removal process such as CMP may be performed on the semiconductor device 500 to planarize the surfaces of the substrate 502 and the backside contacts 520.

The semiconductor device 500 includes a gate 506 (also referred to as a gate region, or gate electrode). The gate 506 comprises one or more suitable electrically conductive metals (e.g., Cu). In certain examples, the gate 506 may be partially formed into the substrate 502. In these examples, prior to forming the gate 506, an amount of the material of the substrate 502 may be removed with a suitable material removal technique, such as etching. It should be appreciated that in other examples a bottom surface of the gate 506 may be flush with a top surface of the substrate 502.

As also shown in FIG. 5, source/drain epitaxial layers 504 are formed on each side of the gate 506. In certain examples, the gate 506 extends above an upper surface of the source/drain epitaxial layers 504. In certain embodiments, a gate electrode spacer layer 508 is formed on both sides of the gate 506. The gate electrode spacer layer 508 may comprise one or more suitable dielectric materials. Also, an interlayer dielectric (ILD) layer 510 is formed on the source/drain epitaxial layers 504 and the gate electrode spacer layer 508. The ILD layer 510 may comprise one or more suitable dielectric materials. As shown in FIG. 5, the gate electrode spacer layer 508 is formed on the sides of the gate 506, and is formed between the gate 506 and the ILD layer 510. After the formation of the ILD layer 510, a suitable material removal process may be used to form a trench (not shown) in the ILD layer 510 that expose the upper surface of the source/drain epitaxial layer 504 that is located to the left of the gate 506. Then, one or more suitable metallic materials are deposited into the trench and on the source/drain epitaxial layer 504 to form a source/drain contact 512 (also referred to as CA contacts). Also, a similar material removal process is performed on the ILD layer 510 to form another trench (not shown), thereby exposing the gate 506 and a portion of the ILD layer 510. Then, one or more suitable metallic materials are deposited into this trench and the gate contact 514 (also referred to as a CB contact) is formed on the gate 506 and the ILD layer 510. A second ILD layer 550 is formed on the gate contact 514 and the source/drain contact 512. A source/drain contact via 526 is formed in the second ILD layer 550 and lands on the source/drain contact 512, and a gate contact via 534 is formed in the second ILD layer 550 and lands on the gate contact 514.

In the embodiment shown in FIG. 5, the offset between the source/drain contact 512 and the gate contact 514 is increased, similar to the increased offsets that were discussed above. However, in the embodiments of FIG. 5, the gate contact 512 is made to be wider so as to have an extension that is located over the source/drain epitaxial layer 504 to the right of the gate 506. The gate contact 512 is also wider than the gate contact 314 of FIG. 3 to allow for the landing of the gate contact via 534 thereon. Thus, a distance Y between the gate contact 514 to the source/drain contact 512 is increased relative to the distance X discussed above with respect to FIGS. 1A and 1B (i.e., Y>X), and this may enable an increase in the Vₘₐₓ.

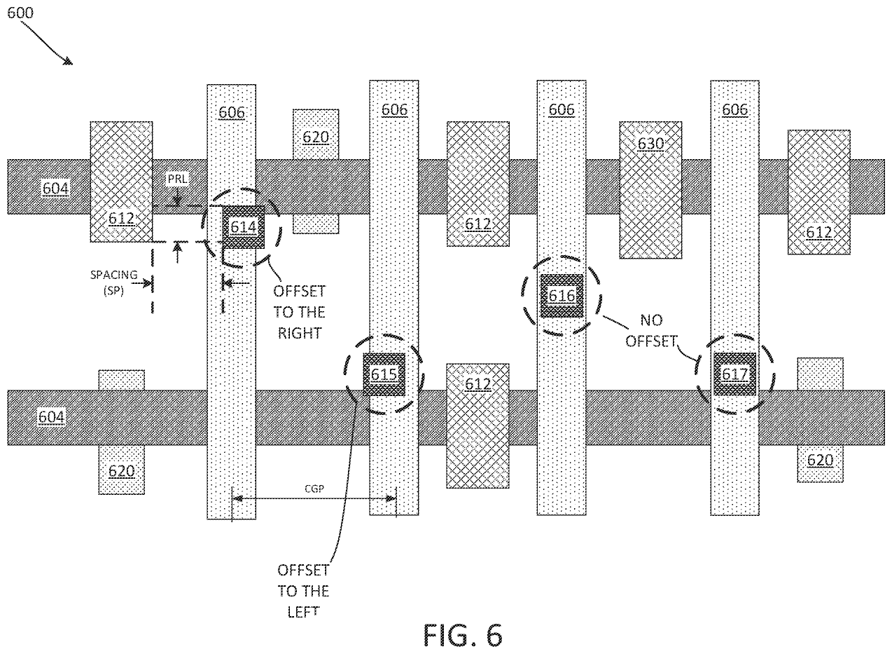

FIG. 6 is a simplified top view of a semiconductor device 600 showing certain gate contacts 614 and 615 that are offset from a centerline of the gate 606, and other gate contacts 616 and 617 that are not offset, according to embodiments. As shown in FIG. 6, the source/drain epitaxial layers 604 (also referred to as the active area (or RX) of the semiconductor device 600) extend in a first direction. The gates 606 extend in a second direction that is orthogonal to the first direction. The gates 606 intersect with the active area of the source/drain epitaxial layers 604. A number of backside contacts 620 are formed under the source/drain epitaxial layers 604. The backside contacts 620 may be a drain contact (or VDD contact) or a source contact (or VSS contact). A number of the source/drain contacts 612 (also referred to as CA) are formed over the source/drain epitaxial layers 604, and a number of gate contacts 614, 615, 616, 617 (also referred to as CB) are formed over the gates 606.

In the example shown in FIG. 6, the gate contact 614 is offset to the right to increase the distance between the gate contact 614 and the source/drain contact 612. Also, the gate contact 615 is offset to the left to increase the distance between the gate contact 615 and the source/drain contact 612. Also, because the gate contact 616 does not overlap the source/drain epitaxial layer 604 in plan view and does not have proximity to (or is not adjacent to) any of the source/drain contacts 612, the gate contact 616 is not offset (i.e., offsetting could be done for gate contact 616, but it would not have the same benefit of increased Vₘₐₓ as in the cases of gate contacts 614 and 615). Finally, even though the gate contact 617 does overlap the source/drain epitaxial layer 604 in plan view, it is not offset because it does not have proximity to any of the source/drain contacts 612 (i.e., offsetting could be done for gate contact 617, but it would not have the same benefit of increased Vₘₐₓ as in the cases of gate contacts 614 and 615).

With regard to the term “adjacent” used herein as it relates to the various embodiments, “adjacent” refers to the “spacing” between two shapes (e.g., the gate contact and the source/drain contact) when there is a “parallel run length” (PRL). As shown in FIG. 6, the “parallel run length” between the gate contact 614 and the source/drain contact 612 indicates that there is a certain amount of overlap in the vertical direction (a direction from the top to the bottom as shown in FIG. 6) between the edges of the gate contact 614 and the source/drain contact 612. In another example, there is no “parallel run length” between gate contact 616 and any of the source/drain contacts 612 because there is no overlap in the vertical direction between the edges of the gate contact 616 and the source/drain contacts 612. Also, the “spacing” (SP) between any of the gate contacts and the source/drain contacts is defined as the distance between the “parallel run length” edges. If the two shapes don't share any parallel run length, (i.e., parallel run length=0), the spacing between these two shapes is not a factor in determining whether the objects are adjacent to each other. In other words, two objects are determined not to be “adjacent” when there is no parallel run length. When there is some amount of “parallel run length,” and when the gate contact and the source/drain contact “spacing” is less than the contacted gate pitch (CGP), as shown in FIG. 6, the gate contact is considered to be “adjacent” to the source/drain contact. Contacted gate pitch is the distance between centerlines of adjacent gates 606. In certain examples, the CGP may be about 50 nm. However, it should be appreciated that the CGP may be any other suitable length. It should be appreciated that the term “adjacent” may apply to any of the embodiments discussed herein.

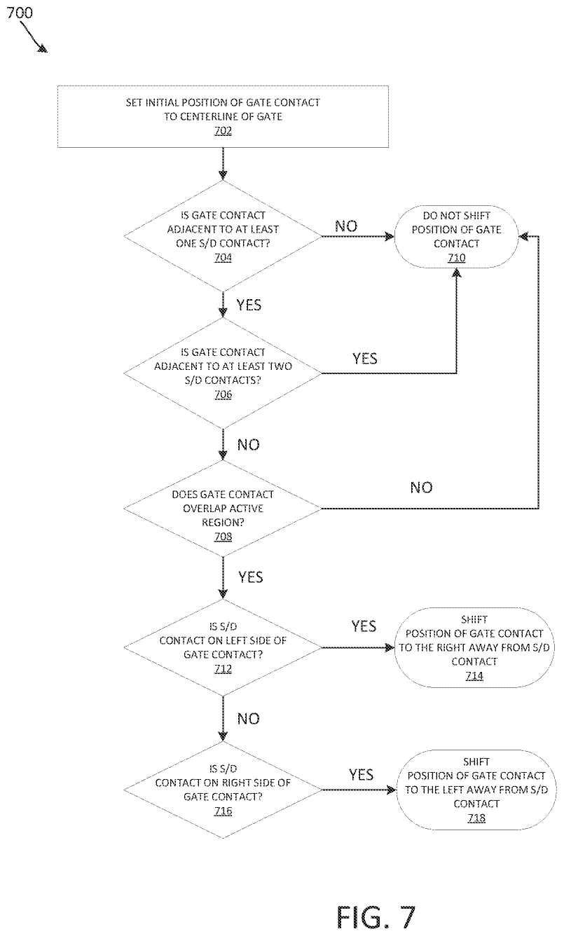

Referring now to FIG. 7, a method 700 of setting a position of a gate contact relative to a centerline of a gate region for a semiconductor device is provided, according to embodiments. At operation 702, the method includes setting an initial position of the gate contact so that it is aligned with the centerline (CL) of the gate (or gate region).

At operation 704, the method includes determining if the gate contact is adjacent to a least one source/drain (or S/D) contact. It should be appreciated that the term “adjacent to” may mean that the gate contact is less than a predetermined distance from the source/drain contact, as described above with respect to FIG. 6. At operation 704, if the determination is that the gate contact is not adjacent to at least one source/drain contact (704: NO), then at operation 710 do not shift the position of the gate contact. At operation 704, if the determination is that the gate contact is adjacent to at least one source/drain contact (704: YES), then the process continues to operation 706.

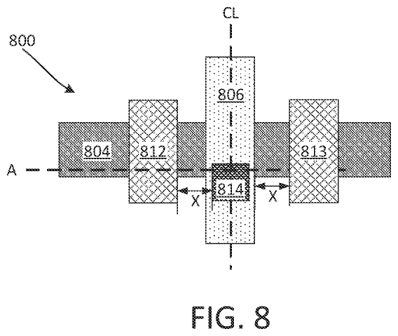

At operation 706, the method includes determining if the gate contact is adjacent to a least two source/drain contacts. At operation 706, if the determination is that the gate contact is not adjacent to at least two source/drain contacts (706: NO), then the process continues to operation 708. At operation 706, if the determination is that the gate contact is adjacent to at least two source/drain contacts (706: YES), then at operation 710 do not shift the position of the gate contact. The reason for this is that if, as shown in the example of FIG. 8, there are source/drain contacts 812 and 813 on both sides of the gate contact 814, moving the gate contact 814 away from source/drain contact 812 could undesirably move the gate contact 814 too close to the source/drain contact 813. FIG. 8 also shows semiconductor device 800, source/drain epitaxial regions 804, and gate 806.

At operation 708, the method includes determining if the gate contact at least partially overlaps in plan view the source/drain epitaxial layers that are included in the active region of the semiconductor device. At operation 708, if the determination is that the gate contact does not overlap in plan view the source/drain epitaxial layers (708: NO), then at operation 710 do not shift the position of the gate contact. For example, as shown in FIG. 6, gate contact 616 is between two different source/drain epitaxial layers 604 and is not in close enough proximity to the source/drain contacts 612 to cause a problem with lowering the Vₘₐₓ. At operation 708, if the determination is that the gate contact does at least partially overlap in plan view the source/drain epitaxial layers (708: YES), then the process continues to operation 712.

At operation 712, the method includes determining if the source/drain contact is located on the left side of the gate contact of the semiconductor device. At operation 712, if the determination is that the source/drain contact is located on the left side of the gate contact (712: YES), then at operation 714 shift the position of the gate contact to the right and away from the source/drain contact so that the gate contact is offset from the centerline of the gate. At operation 712, if the determination is that source/drain contact is not located on the left side of the gate contact (712: NO), then the process continues to operation 716.

At operation 716, the method includes determining if the source/drain contact is located on the right side of the gate contact of the semiconductor device. At operation 716, if the determination is that the source/drain contact is located on the right side of the gate contact (716: YES), then at operation 718 shift the position of the gate contact to the left away from the source/drain contact so that the gate contact is offset from the centerline of the gate.

With respect to the method 700 shown and described with respect to FIG. 7, it should be appreciated that the order of operations may be changed. For example, operation 708 (i.e., determining overlap in plan view with the active region) may occur before operation 704 (i.e., determining if gate contact is adjacent to at least one source/drain contact). It should also be appreciated that operations 712 and 716 may be considered more generally as a single operation of determining where the source/drain contact is relative to the gate contact so that a direction of offset away from the source/drain contact can be determined. It should also be appreciated that the designations of right side and left side are merely one example, and depending on the perspective or the layout of the semiconductor device, the top and bottom sides may be considered as well.

As discussed herein, the present embodiments allow for the gate contact to be shifted away from the source/drain contact, and this may enable an increase in the Vₘₐₓ.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
an active region;
a gate;
a gate contact formed on the gate, the gate contact overlapping in plan view with at least a portion of the active region; and
a source/drain contact formed on the active region and adjacent to the gate contact,
wherein the gate contact is offset from a centerline of the gate in a direction away from the source/drain contact.

2. The semiconductor device of claim 1, wherein the active region includes at least one source/drain epitaxial layer.

3. The semiconductor device of claim 2, wherein the source/drain contact is formed on the source/drain epitaxial layer.

4. The semiconductor device of claim 1, further comprising a substrate and a backside contact formed in the substrate, the backside contact formed on a side of the gate opposite to where the source/drain contact is located.

5. The semiconductor device of claim 1, wherein the gate contact extends beyond an edge of the gate on a side of the gate opposite to where the source/drain contact is located.

6. The semiconductor device of claim 5, further comprising a gate contact via formed on an extension portion of the gate contact.

7. The semiconductor device of claim 1, wherein the gate contact partially covers the gate.

8. The semiconductor device of claim 7, wherein a portion of the gate that is not covered by the gate contact is on a side of the gate nearer to the source/drain contact.

9. The semiconductor device of claim 1, wherein the gate contact extends across a source/drain epitaxial layer and contacts a second gate.

10. The semiconductor device of claim 9, wherein the gate contact only partially covers the gate and only partially covers the second gate.

11. The semiconductor device of claim 9, further comprising a second source/drain contact in the active region adjacent to the second gate.

12. The semiconductor device of claim 11, wherein the gate contact is offset from a centerline of the second gate in a direction away from the second source/drain contact.

13. The semiconductor device of claim 9, further comprising a substrate and a backside contact formed in the substrate, the backside contact formed underneath the gate contact.

14. A semiconductor device comprising:
an active region;
a first gate and a second gate;
a first gate contact formed on the first gate, and a second gate contact formed on the second gate, the first and second gate contacts overlapping in plan view with at least a portion of the active region; and
a first source/drain contact on the active region and adjacent to the first gate contact, and a second source/drain contact on the active region and adjacent to the second gate contact,
wherein the first gate contact is offset from a centerline of the first gate in a first offset direction away from the first source/drain contact,
wherein the second gate contact is offset from a centerline of the second gate in a second offset direction away from the second source/drain contact, and
wherein the first offset direction is different from the second offset direction.

15. The semiconductor device of claim 14, wherein the active region includes at least one source/drain epitaxial layer.

16. The semiconductor device of claim 15, wherein the first and second source/drain contacts are formed on the source/drain epitaxial layer.

17. The semiconductor device of claim 14, further comprising a substrate and a backside contact formed in the substrate, the backside contact formed on a side of the first gate opposite to where the first source/drain contact is located.

18. The semiconductor device of claim 14, wherein the first gate contact extends beyond an edge of the first gate on a side of the first gate opposite to where the first source/drain contact is located.

19. The semiconductor device of claim 14, wherein the first gate contact partially covers the first gate.

20. The semiconductor device of claim 19, wherein a portion of the first gate that is not covered by the first gate contact is on a side of the first gate nearer to the first source/drain contact.
